(19) United States
(12) Patent Application Publication
(10) Pub. No.: US 2025/0227901 A1
(43) Pub. Date: Jul. 10, 2025

(54) ROLLABLE ELECTRONIC DEVICE COMPRISING HEAT DISSIPATION MEMBER

(71) Applicant: Samsung Electronics Co., Ltd., Suwon-si (KR)

(72) Inventors: Baekeun CHO, Suwon-si (KR); Moonsun KIM, Suwon-si (KR); Junhyuk KIM, Suwon-si (KR); Hoyoung JEONG, Suwon-si (KR); Sukdong KIM, Suwon-si (KR); Soohyun SEO, Suwon-si (KR); Hyunju HONG, Suwon-si (KR)

(21) Appl. No.: 19/089,890

(22) Filed: Mar. 25, 2025

Related U.S. Application Data
(63) Continuation of application No. PCT/KR2023/014931, filed on Sep. 26, 2023.

(30) Foreign Application Priority Data
Sep. 28, 2022 (KR) 10-2022-0123281
Nov. 22, 2022 (KR) 10-2022-0157557

(51) Int. Cl. H05K 7/20; H04M 1/02

(52) U.S. Cl. CPC H05K 7/20963; H04M 1/0235; H04M 1/0268; H04M 1/0277

(57) ABSTRACT

An electronic device is provided. The electronic device includes a first housing having a first cover member, and a frame disposed within the first cover member, the frame including an outer surface, a second housing having a second cover member, at least a portion of which is accommodated within the first cover member, wherein the second housing is configured to slide relative to the first housing, a display configured to be unfolded based on a sliding movement of the second housing, a circuit board disposed on the second cover member and accommodating an application processor, and a heat dissipation member disposed between the circuit board and the frame.

### CROSS-REFERENCE TO RELATED APPLICATION(S)

This application is a continuation application, claiming priority under 35 U.S.C. § 365(c), of an International application No. PCT/KR2023/014931, filed on Sep. 26, 2023, which is based on and claims the benefit of a Korean patent application number 10-2022-0123281, filed on Sep. 28, 2022, in the Korean Intellectual Property Office, and of a Korean patent application number 10-2022-0157557, filed on Nov. 22, 2022, in the Korean Intellectual Property Office, the disclosure of each of which is incorporated by reference herein in its entirety.

### BACKGROUND

### 1. Field

The disclosure relates to a rollable electronic device including a heat dissipation member.

### 2. Description of Related Art

Due to the advancement of information and communication technology and semiconductor technology, various functions are being integrated into a single portable electronic device. For example, an electronic device may implement not only communication functions, but also entertainment functions such as games, multimedia functions such as music/video playback, communication and security functions for mobile banking, schedule management functions, and electronic wallet functions. Such electronic devices are becoming more compact to be conveniently carriable by a user.

As mobile communication services expand into the area of multimedia services, there is a need to increase the size of a display of an electronic device in order for a user to fully utilize multimedia services as well as voice calls and short messages services. However, the size of a display of an electronic device is in a trade-off relationship with the miniaturization of the electronic device.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide a rollable electronic device including a heat dissipation member.

Additional aspects will be set forth in part in the description which follows and, in part, will be apparent from the description, or may be learned by practice of the presented embodiments.

In accordance with an aspect of the disclosure, an electronic device is provided. The electronic device includes a first housing having a first cover member, and a frame disposed within the first cover member, the frame including an outer surface, a second housing having a second cover member, at least a portion of which is accommodated within the first cover member, wherein the second housing is configured to slide relative to the first housing, a display configured to be unfolded based on a sliding movement of the second housing, a circuit board disposed on the second cover member and accommodating an application processor, and a heat dissipation member disposed between the circuit board and the frame.

In accordance with another aspect of the disclosure, an electronic device is provided. The electronic device includes a first housing, a second housing configured to slide relative to the first housing, a display configured to be unfolded based on the sliding movement of the second housing, a circuit board disposed in the second housing and accommodating a processor, a connection member including a first end disposed in the first housing and a second end disposed in the second housing, and a heat dissipation member disposed on the connection member, the heat dissipation member being configured to be in contact with the circuit board and the first housing in a slide-in state of the electronic device.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an electronic device in a network environment according to an embodiment of the disclosure;

FIG. 2 is a view showing a state in which a second display area of a display is accommodated in a housing according to an embodiment of the disclosure;

FIG. 3 is a view showing a state in which a second display area of a display is exposed to the outside of a housing according to an embodiment of the disclosure;

FIG. 4 is an exploded perspective view of an electronic device according to an embodiment of the disclosure;

FIG. 5A is a cross-sectional view taken along line A-A′ in FIG. 2 according to an embodiment of the disclosure;

FIG. 5B is a cross-sectional view taken along line B-B′ in FIG. 3 according to an embodiment of the disclosure;

FIG. 6 is a perspective view of a drive structure according to an embodiment of the disclosure;

FIG. 7 is an exploded perspective view of an electronic device according to an embodiment of the disclosure;

FIG. 8 is a rear view of an electronic device including a heat dissipation member according to an embodiment of the disclosure;

FIG. 9 is a cross-sectional view taken along line C-C′ in FIG. 8 according to an embodiment of the disclosure;

FIG. 10 is a cross-sectional view taken along line C-C′ in FIG. 8 according to an embodiment of the disclosure;

FIG. 11A is a rear view in a slide-in state of an electronic device including a connection member according to an embodiment of the disclosure;

FIG. 11B is a rear view in a slide-out state of an electronic device including a connection member according to an embodiment of the disclosure;

FIG. 12 is a rear view of an electronic device including a heat dissipation member and a connection member according to an embodiment of the disclosure;

FIG. 13 is a cross-sectional view taken along line D-D′ in FIG. 12 according to an embodiment of the disclosure;

FIG. 14A is a cross-sectional view taken along line E-E′ in FIG. 12 according to an embodiment of the disclosure;

FIG. 14B is a cross-sectional perspective view taken along line E-E′ in FIG. 12 according to an embodiment of the disclosure;

FIG. 15 is a perspective view of a heat dissipation member and a connection member according to an embodiment of the disclosure; and

FIG. 16 is a perspective view of a connection member to which a graphite sheet and a heat dissipation member are arranged according to an embodiment of the disclosure.

The same reference numerals are used to represent the same elements throughout the drawings.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a Wi-Fi chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

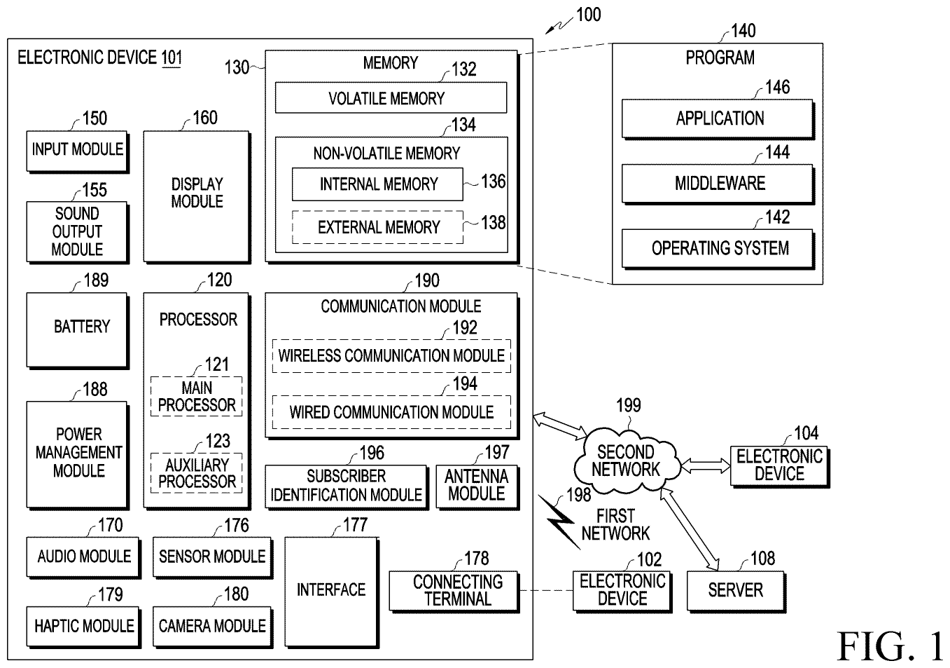

FIG. 1 is a block diagram illustrating an electronic device 101 in a network environment 100 according to an embodiment of the disclosure.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a fifth generation (5G) network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a fourth generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the millimeter wave (mmWave) band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

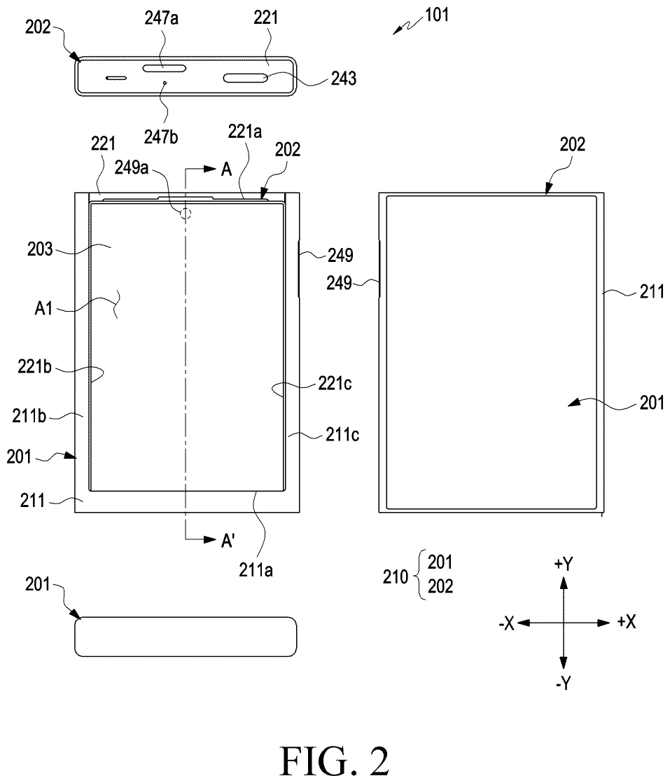

FIG. 2 is a view showing a state in which a second display area of a display is accommodated in a housing according to an embodiment of the disclosure.

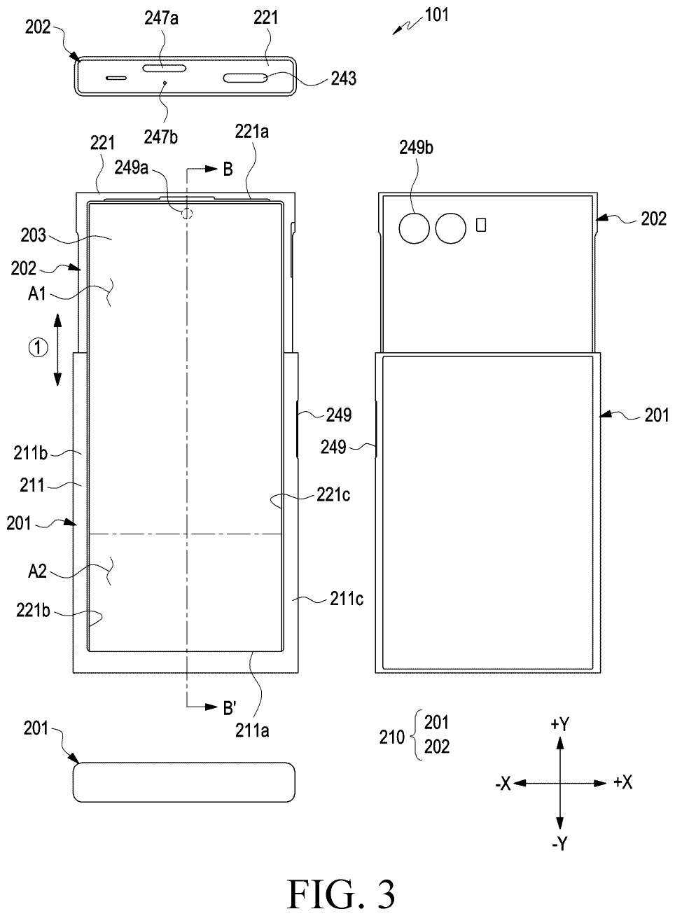

FIG. 3 is a view showing a state in which a second display area of a display is exposed to the outside of a housing according to an embodiment of the disclosure.

FIGS. 2 and 3 show a structure in which a display 203 (e.g., a flexible display or a rollable display) is expanded in the length direction (e.g., the +Y-axis direction) thereof, when viewed from a front face of an electronic device 101. However, the direction, in which the display 203 is expanded, not limited to one direction (e.g., the +Y-axis direction). For example, the display 203 may be expanded in the upward direction (the +Y-axis direction), the right direction (e.g., the +X-axis direction), the left direction (e.g., the −X-axis direction), and/or the downward direction (e.g., the −Y-axis direction) through a design change.

The state illustrated in FIG. 2 may be referred to as a slide-in state of the electronic device 101 or a state in which a second display area A2 of the display 203 is closed.

The state illustrated in FIG. 3 may be referred to as a slide-out state of the electronic device 101 or a state in which a second display area A2 of the display 203 is open.

Referring to FIGS. 2 and 3, the electronic device 101 may include a housing 210. The housing 210 may include a first housing 201 and a second housing 202 disposed to be movable relative to the first housing 201. In an embodiment, it may be interpreted that the electronic device 101 has a structure in which the first housing 201 is disposed to be slidable and movable relative to the second housing 202. According to an embodiment, the second housing 202 may be disposed to be reciprocally movable by a predetermined distance in the illustrated direction with reference to the first housing 201, for example, the direction indicated by arrow (I.

According to an embodiment, the second housing 202 may be referred to as a slide part or a slide housing, and may be relatively movable with respect to the first housing 201. According to an embodiment, the second housing 202 may accommodate various electric and electronic components such as a circuit board or a battery.

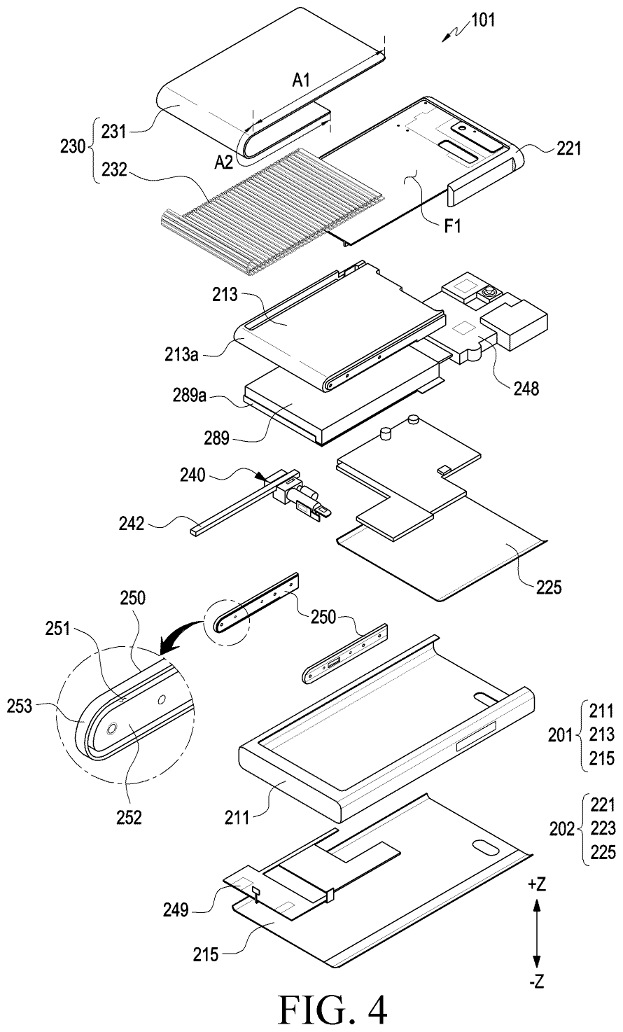

According to an embodiment, the first housing 201 may accommodate a motor, a speaker, a SIM socket, and/or a sub-circuit board (e.g., the second circuit board 249 in FIG. 4) electrically connected to a main circuit board. The second housing 202 may accommodate a main circuit board (e.g., the first circuit board 248 in FIG. 4) to which electrical components such as an application processor (AP) and a communication processor (CP) are mounted.

According to an embodiment, the first housing 201 may include a first cover member 211. The first cover member 211 may include a (1-1)th side wall 211a, a (1-2)th side wall 211b extending from the (1-1)th side wall 211a, and a (1-3)th side wall 211c which extends from the (1-1)th side wall 211a and is substantially parallel to the (1-2)th side wall 211b. According to an embodiment, the (1-2)th side wall 211b and the (1-3)th side wall 211c may be formed to be substantially perpendicular to the (1-1)th side wall 211a. According to an embodiment, the first cover member 211 may be referred to as a main case or a cover member.

According to an embodiment, the (1-1)th side wall 211a, the (1-2)th side wall 211b, and the (1-3)th side wall 211c of the first cover member 211 may be formed in a shape, in which one side (e.g., the front face) thereof is opened, to accommodate (or surround) at least a portion of the second housing 202. For example, at least a portion of the second housing 202 may be surrounded by the first housing 201 and may slide in a direction parallel to a first surface (e.g., the first surface F1 in FIG. 4), for example, in the direction of arrow \textcircled{1}, while being guided by the first housing 201. According to an embodiment, the (1-1)th side wall 211a, the (1-2)th side wall 211b, and/or the (1-3)th side wall 211c of the first cover member 211 may be formed as an integrated type. According to an embodiment, the (1-1)th side wall 211a, the (1-2)th side wall 211b, and/or the (1-3)th side wall 211c of the first cover member 211 may be formed as separate structures and then be coupled or assembled to each other.

According to an embodiment, the first cover member 211 may be formed to surround at least a portion of the display 203. For example, at least a portion of the display 203 may be formed to be surrounded by the (1-1)th side wall 211a, the (1-2)th side wall 211b, and/or the (1-3)th side wall 211c of the first cover member 211.

According to an embodiment, the second housing 202 may include a second cover member 221 (e.g., a slide plate). The second cover member 221 may have a plate shape and may include a first surface (e.g., the first surface F1 in FIG. 4) for supporting internal components. For example, the second cover member 221 may support at least a portion (e.g., the first display area A1) of the display 203. According to an embodiment, the second cover member 221 may be referred to as a front cover.

According to an embodiment, the second cover member 221 may include a (2-1)th side wall 221a, a (2-2)th side wall 221b extending from the (2-1)th side wall 221a, and a (2-3)th side wall 221c which extends from the (2-1)th side wall 221a and is substantially parallel to the (2-2)th side wall 221b. According to an embodiment, the (2-2)th side wall 221b and the (2-3)th side wall 221c may be formed to be substantially perpendicular to the (2-1)th side wall 221a. According to an embodiment, the second cover member 221 may be referred to as an auxiliary cover member.

According to an embodiment, the second housing 202 may move in a first direction (e.g., the direction \textcircled{1}) parallel to the (2-2)th side wall 211b or the (2-3)th side wall 211c, and thus may form a slide-in state and a slide-out state of the electronic device 101. In a slide-in state of the electronic device 101, the second housing 202 may be positioned at a first distance from the (1-1)th side wall 211a of the first housing 201, and in a slide-out state of the electronic device 101, the second housing 202 may move to be positioned at a second distance from the (1-1)th side wall 211a of the first housing 201, the second distance being greater than the first distance. In an embodiment, in a slide-in state of the electronic device 101, the first housing 201 may be formed to surround a portion of the (2-1)th side wall 221a.

According to an embodiment, the electronic device 101 may have an intermediate state between the slide-in state (e.g., the fully open state) in FIG. 2 and the slide-out state (e.g., the fully closed state) in FIG. 3. The distance between the (1-1)th side wall 211a and the (2-1)th side wall 221a in an intermediate state of the electronic device 101 may be shorter than the distance between the (1-1)th side wall 211a and the (2-1)th side wall 221a in a fully open state of the electronic device 101, and may be longer than the distance between the (1-1)th side wall 211a and the (2-1)th side wall 221a in a fully closed state of the electronic device 101. According to an embodiment, in an intermediate state of the electronic device 101, as at least a portion of the display 203 slides, an area of the display, which is exposed to the outside, may be varied. For example, in an intermediate state of the electronic device 101, the ratio of the width (the length in the X-axis direction) and the height (the length in the Y-axis direction) of the display 203, and/or the distance between the (1-1)th side wall 211a and the (2-1)th side wall 221a may be changed based on the sliding movement of the electronic device 101.

According to an embodiment, the electronic device 101 may include the display 203, a key input device 245, a connector hole 243, audio modules 247a and 247b, or camera modules 249a and 249b. According to an embodiment, the electronic device 101 may further include an indicator (e.g., an LED device) or various sensor modules.

According to an embodiment, the display 203 may include a first display area A1 and a second display area A2 configured to be exposed to the outside of the electronic device 101, based on the sliding movement of the second housing 202. According to an embodiment, the first display area A1 may be disposed on the second housing 202. For example, the first display area A1 may be disposed on the second cover member 221 of the second housing 202. According to an embodiment, the second display area A2 may extend from the first display area A1, and may be accommodated in the first housing 201 or be visually exposed to the outside of the electronic device 101 as the second housing 202 slides relative to the first housing 201. According to an embodiment, as the electronic device 101 switches from a slide-out state to a slide-in state, the display 203 may be expanded in the downward direction (e.g., the −Y-axis direction) of the electronic device 101. For example, in a slide-out state of the electronic device 101, the second display area A2 may be visually exposed from under (e.g., the −Y-axis direction) the display 203. According to an embodiment, as the electronic device 101 switches from a slide-out state to a slide-in state, the display 203 may be expanded in the upward direction (e.g., the +Y-axis direction) of the electronic device 101. For example, in a slide-out state of the electronic device 101, the second display area A2 may be visually exposed from above (e.g., the +Y-axis direction) the display 203.

According to an embodiment, the second display area A2 may move while being substantially guided by an area (e.g., a curved surface e in FIG. 4) of the first housing 201, and may be accommodated in a space positioned inside the first housing 201 or be exposed to the outside of the electronic device 101. According to an embodiment, the second display area A2 may move based on the sliding in the first direction (e.g., the direction indicated by arrow (I)) of the second housing 202. For example, while the second housing 202 slides, a portion of the second display area A2 may be transformed into a curved-surface shape at a position corresponding to the curved surface 213a of the first housing 201.

According to an embodiment, when viewed from above the second cover member 221 (e.g., a front cover), in case that the electronic device 101 switches from a slide-in state to a slide-out state (e.g., in case that the second housing 202 slides to expand with respect to the first housing 201), the second display area A2 may be gradually exposed to the outside of the first housing 201 so as to form a substantially flat surface together with the first display area A1. According to an embodiment, the display 203 may be coupled to or disposed adjacent to a touch detection circuit, a pressure sensor capable of measuring the intensity (pressure) of a touch, and/or a digitizer for detecting a magnetic field type of stylus pen. According to an embodiment, regardless of a slide-in state or a slide-out state of the electronic device 101, a part, which is exposed, of the second display area A2 may be positioned on a part (e.g., the curved surface 213a in FIG. 4) of the first housing, and a part of the second display area A2 may maintain a curved-surface shape at a position corresponding to the curved surface 213a.

According to an embodiment, the key input device 245 may be positioned in an area of the housing 210 (e.g., the first housing 201 and/or the second housing 202). According to the outer appearance and use conditions thereof, the electronic device 101 may be designed such that the illustrated key input device 245 is omitted or an additional key input device(s) is included. According to an embodiment, the electronic device 101 may include a key input device not illustrated, for example, a home key button or a touch pad disposed around the home key button. According to an embodiment, at least a portion of the key input device 245 may be positioned on the (1-1)th side wall 211a, the (1-2)th side wall 211b, and/or the (1-3)th side wall 211c of the first housing 201. According to an embodiment, at least a portion of the key input device 245 may be positioned on the (2-1)th side wall 221a, the (2-2)th side wall 221b, and/or the (2-3)th side wall 221c of the second housing 202.

According to an embodiment, the connector hole 243 may be omitted according to an embodiment, and may accommodate a connector (e.g., a USB connector) for transmitting or receiving electric power and/or data to or from an external electronic device. According to an embodiment (not shown), the electronic device 101 may include multiple connector holes 243, and a part of the multiple connector holes 243 may function as a connector hole for transmitting and receiving an audio signal to and from an external electronic device. In the illustrated embodiment, although the connector hole 243 is positioned in the second housing 202, it is not limited thereto, and the connector hole 243 or a connector hole not illustrated may be positioned in the first housing 201.

According to an embodiment, the audio modules 247a and 247b may include at least one speaker hole 247a or at least one microphone hole 247b. One of the speaker holes 247a may be provided as a receiver hole for voice calling, and the other may be provided as a hole for an external speaker. The electronic device 101 may include a microphone for acquiring sound, and the microphone may acquire sound outside the electronic device 101 through the microphone hole 247b. According to an embodiment, the electronic device 101 may include multiple microphones in order to sense a direction of sound. According to an embodiment, the electronic device 101 may include an audio module in which the speaker hole 247a and the microphone hole 247b are implemented as a single hole, or may include a speaker in which the speaker hole 247a is excluded (e.g., a piezo speaker). According to an embodiment, the speaker hole 247a and the microphone hole 247b may be positioned in the first housing 201 and/or the second housing 202.

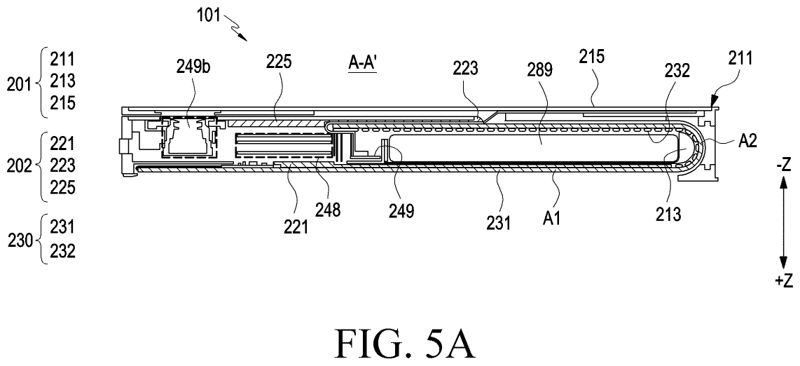

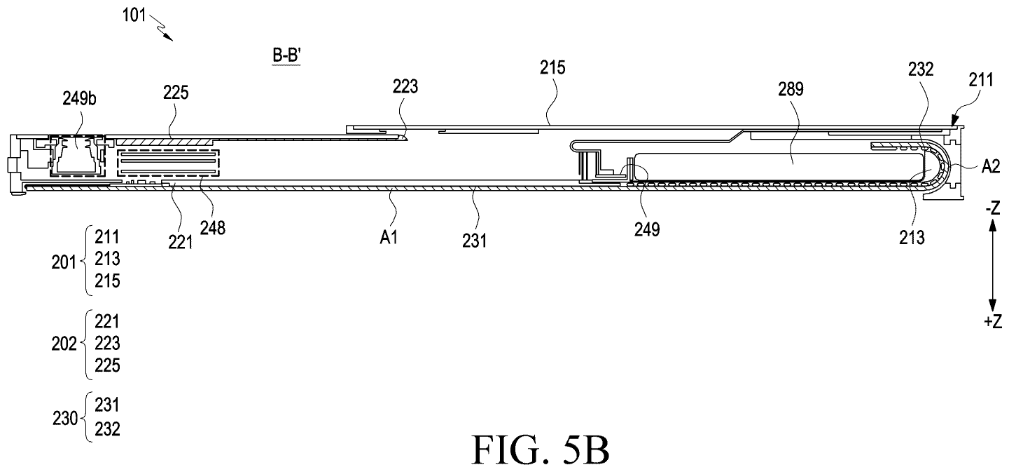

According to an embodiment, the camera modules 249a and 249b may include a first camera module 249a (e.g., a front camera) and second camera modules 249b (e.g., a rear camera) (e.g., the second camera modules 249b in FIGS. 5A and 5B). According to an embodiment, the electronic device 101 may include at least one of a wide-angle camera, a telephoto camera, or a close-up camera, and according to an embodiment, may include an infrared projector and/or an infrared receiver to measure the distance to a subject. Each of the camera modules 249a and 249b may include one lens or multiple lenses, an image sensor, and/or an image signal processor. The first camera module 249a may be disposed to be oriented in the same direction as the display 203. For example, the first camera module 249a may be disposed around the first display area A1 or in an area overlapping the display 203, and may photograph a subject through the display 203 in case of being disposed in an area overlapping the display 203. According to an embodiment, the first camera module 249a may not be visually exposed to a screen display area (e.g., the first display area A1) and may include a hidden display rear camera (an under-display camera (UDC)). According to an embodiment, the second camera modules 249b may photograph a subject in a direction opposite to the first display area A1. According to an embodiment, the first camera module 249a and/or the second camera modules 249b may be arranged on the second housing 202. According to an embodiment, multiple second camera modules 249b may be formed to provide various arrangements. For example, the multiple second camera modules 249b may be arranged along a width direction (the X-axis direction) which is a direction substantially perpendicular to the sliding direction (e.g., the Y-axis direction) of the electronic device 101. As another example, the multiple second camera modules 249b may be arranged along the sliding direction (e.g., the Y-axis direction) of the electronic device 101. As another example, the multiple second camera modules 249b may be arranged along rows and columns of N×M as a matrix.

According to an embodiment, the second camera modules 249b may not be visually exposed to the outside of the electronic device 101 in a slide-in state of the electronic device 101, and may photograph the outside of the electronic device 101 in a slide-out state of the electronic device 101. According to an embodiment, the second camera modules 249b may photograph the outside of the electronic device 101 in a slide-in state and a slide-out state of the electronic device 101. For example, at least a portion (e.g., the first rear plate 215 and/or the second rear plate 225 in FIG. 4) of the housing 210 may be substantially transparent, and the second camera modules 249b may photograph the outside of the electronic device 101 through a first rear plate 215 and/or a second rear plate 225.

According to an embodiment, an indicator (not shown) of the electronic device 101 may be positioned in the first housing 201 or the second housing 202, and may include a light emitting diode to provide state information of the electronic device 101 as a visual signal. A sensor module (not shown) of the electronic device 101 may generate an electrical signal or a data value corresponding to an internal operation state of the electronic device 101 or an external environmental state. For example, the sensor module may include a proximity sensor, a fingerprint sensor, or a biometric sensor (e.g., an iris/face recognition sensor or an HRM sensor). In another embodiment, for example, the sensor module may further include at least one of a gesture sensor, a gyro sensor, a barometric pressure sensor, a magnetic sensor, an acceleration sensor, a grip sensor, a color sensor, an infrared (IR) sensor, a temperature sensor, a humidity sensor, or an illuminance sensor. According to an embodiment, the sensor module may be positioned in the first housing 201 and/or the second housing 202. For example, at least a portion of the sensor modules may be positioned in the first housing 201 and other parts may be positioned in the second housing 202.

FIG. 4 is an exploded perspective view of an electronic device according to an embodiment of the disclosure. For example, FIG. 4 is a rear exploded perspective view of an electronic device 101 according to an embodiment.

FIG. 5A is a cross-sectional view taken along line A-A′ in FIG. 2 according to an embodiment of the disclosure.

FIG. 5B is a cross-sectional view taken along line B-B′ in FIG. 3 according to an embodiment of the disclosure.

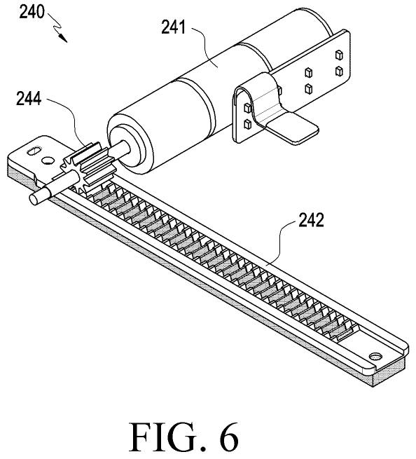

FIG. 6 is a perspective view of a drive structure according to an embodiment of the disclosure.

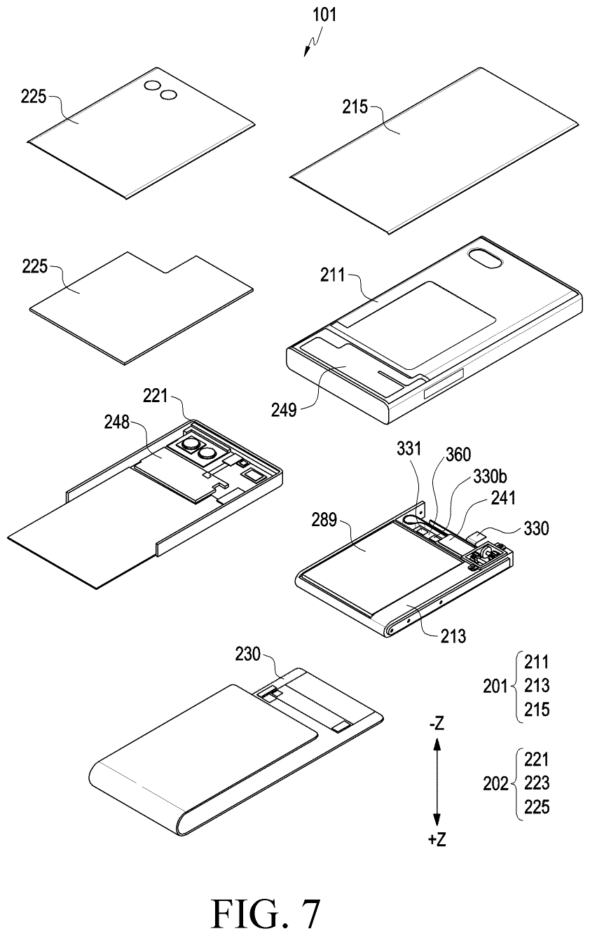

FIG. 7 is an exploded perspective view of an electronic device according to an embodiment of the disclosure. For example, FIG. 7 is a rear exploded perspective view of an electronic device 101 according to an embodiment.

Referring to FIGS. 4, 5A, 5B, 6 and/or 7, an electronic device 101 may include a first housing 201, a second housing 202, a display assembly 230, and a drive structure 240. The configuration of the first housing 201, the second housing 202, and the display assembly 230 in FIGS. 4, 5A, and/or 5B may be entirely or partially the same as the configuration of the first housing 201, the second housing 202, and the display 203 in FIGS. 2 and/or 3. The embodiment of FIG. 2 and/or FIG. 3 may be partially combined with the embodiment of FIGS. 4, 5A, 5B, 6 and/or 7. According to an embodiment, the first housing 201 may include a first cover member 211 (e.g., the first cover member 211 in FIGS. 2 and 3), a frame 213, and a first rear plate 215.

According to an embodiment, the first cover member 211 may accommodate at least a portion of the frame 213 and may accommodate a component (e.g., the battery 289) positioned on the frame 213. According to an embodiment, the first cover member 211 may be formed to surround at least a portion of the second housing 202. According to an embodiment, the first cover member 211 may protect components (e.g., the second circuit board 249 and the frame 213) positioned in the first housing 201 from external impact. According to an embodiment, a second circuit board 249 configured to accommodate an electronic component may be connected to the first cover member 211.

According to an embodiment, the frame 213 may be connected to the first cover member 211. For example, the frame 213 may be connected to the first cover member 211, and the second housing 202 may relatively move with respect to the first cover member 211 and/or the frame 213. According to an embodiment, the frame 213 may accommodate a battery 289. For example, the frame 213 may include a groove configured to accommodate the battery 289. The frame 213 may be connected to the battery cover 289a and may surround at least a portion of the battery 289 together with a battery cover 289a. According to an embodiment, the frame 213 may include a curved-surface part 213a facing the display assembly 230.

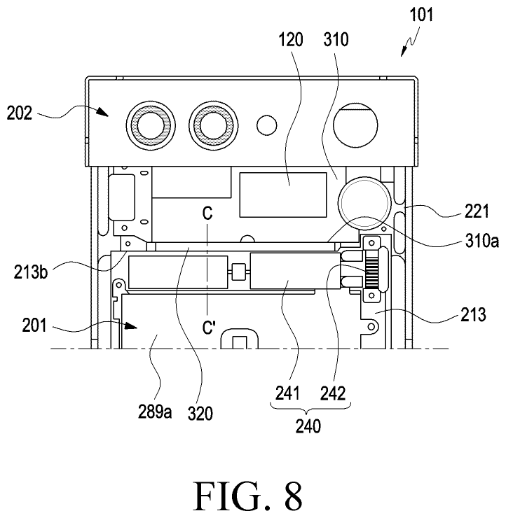

According to an embodiment, the frame 213 may accommodate at least one circuit board (e.g., a third circuit board 360). A third circuit board 360 may be electrically connected to a first circuit board 248 (e.g., the circuit board 310 in FIG. 8) by using a connection member (e.g., the connection member 330 in FIG. 8). The third circuit board 360 may be electrically connected to the battery 289. For example, a battery connector connected to the battery 289 may be mounted to the third circuit board 360.

According to an embodiment, the first rear plate 215 may substantially form the first housing 201 or at least a portion of the exterior of the electronic device 101. For example, the first rear plate 215 may be coupled to an outer surface of the first cover member 211. According to an embodiment, the first rear plate 215 may provide a decorative effect to the exterior of the electronic device 101. The first rear plate 215 may be made of at least one of metal, glass, synthetic resin, or ceramic.

According to an embodiment, the second housing 202 may include a second cover member 221 (e.g., the second cover member 221 in FIGS. 2 and 3), a rear cover 223, and a second rear plate 225.

According to an embodiment, the second cover member 221 may be connected to the first housing 201 through a guide rail 250 and may reciprocate in one direction (e.g., the direction of arrow \textcircled{1} in FIG. 3) while being guided by the guide rail 250.

According to embodiments, the second cover member 221 may support at least a portion of the display 203. For example, the second cover member 221 may include a first surface F1, and a first display area A1 of the display 203 may be substantially positioned on the first surface F1 and be maintained in a flat-plate shape. According to an embodiment, the second cover member 221 may be formed of a metal material and/or a non-metal (e.g., polymer) material. According to an embodiment, the first circuit board 248 configured to accommodate electronic components (e.g., the processor 120 and/or the memory 130 in FIG. 1) may be connected to the second cover member 221. According to an embodiment, the second cover member 221 may protect components (e.g., the first circuit board 248 and the rear cover 223) positioned in the second housing 202 from external impact.

According to an embodiment, the rear cover 223 may protect a component (e.g., the first circuit board 248) positioned in the second cover member 221. For example, the rear cover 223 may be connected to the second cover member 221 and be formed to surround at least a portion of the first circuit board 248. According to an embodiment, the rear cover 223 may include an antenna pattern configured to communicate with an external electronic device. For example, the rear cover 223 may include a laser direct structuring (LDS) antenna.

According to an embodiment, the second rear plate 225 may substantially form the second housing 202 or at least a portion of the exterior of the electronic device 101. For example, the second rear plate 225 may be coupled to an outer surface of the second cover member 221. According to an embodiment, the second rear plate 225 may provide a decorative effect to the exterior of the electronic device 101. The second rear plate 225 may be made of at least one of metal, glass, synthetic resin, or ceramic.

According to embodiments, the display assembly 230 may include a display 231 (e.g., the display 203 in FIGS. 2 and/or 3) and a multi-bar structure 232 configured to support the display 203. According to an embodiment, the display 231 may be referred to as a flexible display, a foldable display, and/or a rollable display. According to an embodiment, the first display area A1 of the display 231 may be supported by a rigid body, and the second display area A2 may be supported by a bendable structure. For example, the first display area A1 may be supported by the first surface F1 of the second cover member 221 or a plate not shown. The second display area A2 may be supported by the multi-bar structure 232.

According to an embodiment, the multi-bar structure 232 may be connected or attached to at least a portion (e.g., the second display area A2) of the display 231. According to an embodiment, as the second housing 202 slides, the multi-bar structure 232 may move relative to the first housing 201. In a slide-in state (e.g., FIG. 2) of the electronic device 101, most of the multi-bar structure 232 may be accommodated in the first housing 201 and be positioned between the first cover member 211 and the second cover member 221. According to an embodiment, at least a portion of the multi-bar structure 232 may move to correspond to the curved surface 213a positioned at an edge of the frame 213. According to an embodiment, the multi-bar structure 232 may be referred to as a display support member or support structure, and may be one plate shape having elasticity.

According to an embodiment, the drive structure 240 may relatively move the second housing 202 with respect to the first housing 201. For example, the drive structure 240 may include a motor 241 configured to generate a drive force for sliding the second housing 202 relative to the first housing 201. The drive structure 240 may include a gear 244 (e.g., a pinion) connected to the motor 241 and a rack 242 configured to mesh with the gear.

According to an embodiment, the housing in which the rack 242 is positioned and the housing in which the motor 241 is positioned may be different. According to an embodiment, the motor 241 may be connected to the second housing 202, and the rack 242 may be connected to the first housing 201. According to an embodiment (e.g., FIG. 7), the motor 241 may be connected to the first housing 201, and the rack 242 may be connected to the second housing 202 (e.g., the second cover member 221). For example, the motor 241 may be mounted on a frame 213.

According to an embodiment, the motor 241 may be controlled by a processor (e.g., the processor 120 in FIG. 1). For example, the processor 120 may include a motor driver driving circuit and may transmit a pulse width modulation (PWM) signal to the motor 241 in order to control the speed of the motor 241 and/or the torque of the motor 241. According to an embodiment, the motor 241 may be electrically connected to a processor (e.g., the processor 120 in FIG. 1) positioned on a circuit board (e.g., the circuit board 204 in FIG. 4) by using a flexible printed circuit board.

According to an embodiment, the second housing 202 may accommodate the first circuit board 248 (e.g., a main board). According to an embodiment, a processor, memory, and/or an interface may be mounted on the first circuit board 248. For example, the processor may include one or more of a central processing device, an application processor, a graphic processing device, an image signal processor, a sensor hub processor, and a communication processor. According to various embodiments, the first circuit board 248 may include a flexible printed circuit board type radio frequency cable (FRC). The first circuit board 248 may be disposed on at least a portion of the second cover member 221 and may be electrically connected to an antenna module and a communications module.

According to an embodiment, for example, the memory may include a volatile memory or a non-volatile memory.

According to an embodiment, for example, the interface may include a high definition multimedia interface (HDMI), a universal serial bus (USB) interface, an SD card interface, and/or an audio interface. For example, the interface may electrically or physically connect the electronic device 101 to an external electronic device, and may include a USB connector, an SD card/multimedia card (MMC) connector, or an audio connector.

According to an embodiment, the electronic device 101 may include a second circuit board 249 (e.g., a sub-circuit board) which is spaced apart from the first circuit board 248 (e.g., a main circuit board) in the first housing 201. The second circuit board 249 may be electrically connected to the first circuit board 248 through a connection flexible substrate. The second circuit board 249 may be electrically connected to electrical components, such as the battery 289 or a speaker and/or a SIM socket, which are arranged in an end area of the electronic device 101, to transmit a signal and electric power. According to an embodiment, the second circuit board 249 may accommodate a wireless charging antenna (e.g., coil) or be connected to a wireless charging antenna. For example, the battery 289 may receive electric power from an external electronic device by using the wireless charging antenna. As another example, the battery 289 may transmit electric power to an external electronic device by using the wireless charging antenna.

According to an embodiment, the battery 289 may be a device for supplying electric power to at least one element of the electronic device 101, and may include a non-rechargeable primary cell, a rechargeable secondary cell, or a fuel cell. The battery 289 may also be integrally disposed inside the electronic device 101, or may also be disposed to be detachable/attachable from/to the electronic device 101. According to an embodiment, the battery 289 may be formed as an integral single battery or may include multiple separate batteries. According to an embodiment, the battery 289 may be positioned on the frame 213. For example, the battery 289 may be surrounded by the frame 213 and the battery cover 289a. According to another embodiment, the battery may be positioned in the second housing 202 and slide together with the second housing 202.

According to an embodiment, the guide rail 250 may guide a movement of the multi-bar structure 232. For example, the multi-bar structure 232 may slide along a slit 251 formed on the guide rail 250. According to an embodiment, the guide rail 250 may be connected to the first housing 201. For example, the guide rail 250 may be connected to the first cover member 211 and/or the frame 213. According to an embodiment, the slit 251 may be referred to as a groove or a recess formed on an inner surface of the guide rail 250.

According to an embodiment, the guide rail 250 may provide a force to the multi-bar structure 232, based on the driving of the motor 241.

According to an embodiment, in case that the electronic device 101 switches from a slide-in state to a slide-out state, an inner portion 252 of the guide rail 250 may provide a force to the multi-bar structure 232. The multi-bar structure 232 having received a force may move along the slit 251 of the guide rail 250, and the second housing 202 may slide to expand with respect to the first housing 201. At least a portion of the display assembly 230 accommodated between the first cover member 211 and the frame 213 may be expanded toward the front face.

According to an embodiment, in case that the electronic device 101 switches from a slide-out state to a slide-in state, an outer portion 253 of the guide rail 250 may provide a force to the bent multi-bar structure 232. The multi-bar structure 232 having received a force may move along the slit 251 of the guide rail 250, and at least a portion of the second housing 202 may slide to be accommodated in the first housing 201. At least a portion of the display assembly 230 may be accommodated between the first cover member 211 and the frame 213.

Referring to FIG. 5A, in a slide-in state of the electronic device 101, at least a portion of the second housing 202 may be disposed to be accommodated in the first housing 201. As the second housing 202 is disposed to be accommodated in the first housing 201, the overall volume of the electronic device 101 may be reduced. According to an embodiment, in case that the second housing 202 is accommodated in the first housing 201, the size of the visually exposed display 231 may be minimized. For example, in case that the second housing 202 is fully accommodated in the first housing 201, the first display area A1 of the display 231 may be visually exposed, and at least a portion (e.g., the part facing the −Z-axis) of the second display area A2 may be positioned between the battery 289 and the first rear plate 215.

Referring to FIG. 5B, in a slide-out state of the electronic device 101, at least a portion of the second housing 202 may protrude from the first housing 201. As the second housing 202 protrudes from the first housing 201, the overall volume of the electronic device 101 may be increased. According to an embodiment, in case that the second housing 202 protrudes from the first housing 201, at least a portion of the second display area A2 of the display 231 may be visually exposed to the outside of the electronic device 101 together with the first display area A1.

FIG. 8 is a rear view of an electronic device including a heat dissipation member according to an embodiment of the disclosure.

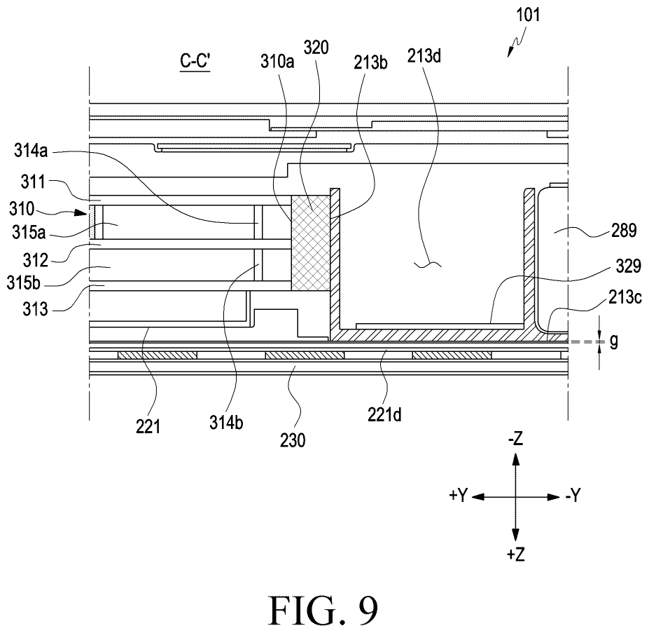

FIG. 9 is a cross-sectional view taken along line C-C′ in FIG. 8 according to an embodiment of the disclosure.

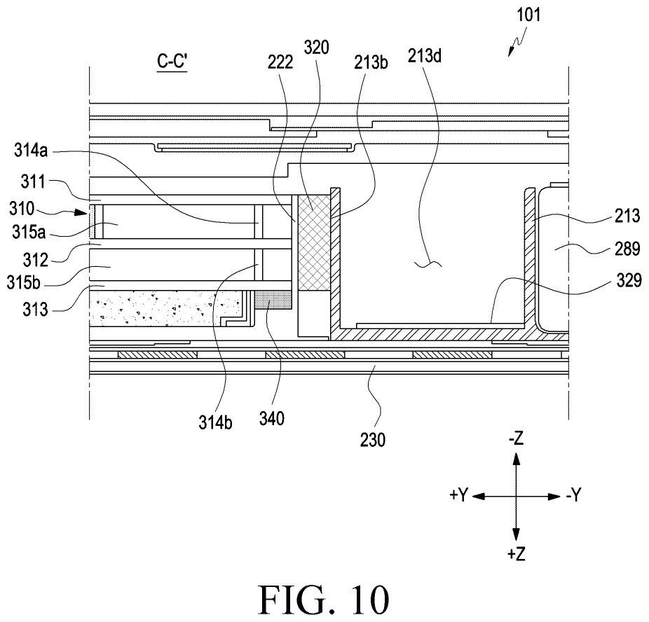

FIG. 10 is a cross-sectional view taken along line C-C′ in FIG. 8 according to an embodiment of the disclosure.

Referring to FIGS. 8, 9, and/or 10, an electronic device 101 may include a processor 120, a frame 213, a second cover member 221, a display assembly 230, a battery 289, a drive structure 240, a circuit board 310, and a heat dissipation member 320. The configuration of the processor 120, the frame 213, the second cover member 221, the display assembly 230, the battery 289, and the drive structure 240 in FIGS. 8, 9, and/or 10 may be entirely or partially the same as the configuration of the processor 120, the frame 213, the second cover member 221, the display assembly 230, the battery 289, and the drive structure 240 in FIG. 1, 4, or 6. The configuration of the circuit board 310 in FIGS. 8 and 9 may be entirely or partially the same as the configuration of the first circuit board 248 in FIG. 4 or 7.

According to an embodiment, the circuit board 310 may accommodate the processor 120. Heat generated in the processor 120 may be transferred to other components of the electronic device 101 through the circuit board 310. As the heat generated by an operation of the processor 120 is transferred to other components (e.g., the battery 287 and/or the frame 213) of the electronic device 101, the internal temperature of the processor 120 and/or the surface temperature of the processor 120 may be reduced. For example, in case that the circuit board 310 positioned in the second housing 202 (e.g., the second cover member 221) comes into contact with the first housing 201 (e.g., the frame 213), heat may be transferred through heat conduction so that heat transfer efficiency is improved. The processor 120 may be an application processor (AP).

According to an embodiment, the circuit board 310 may be a multi-layer board including multiple boards. For example, the circuit board 310 may include a first board 311, a second board 312, and a third board 313 which are stacked on each other. The first board 311 may be referred to as a primary board. The second board 312 may be referred to as a secondary board. The third board 313 may be referred to as a master board. According to an embodiment, the circuit board 310 may be an interposer substrate. For example, the circuit board 310 may include interposers 314a and 314b. The interposers 314a and 314b may electrically connect the multiple boards 311, 312, and 313. For example, the interposers 314a and 314b may include a first interposer 314a which is positioned between the first board 311 and the second board 312 and connects the first board 311 and the second board 312, and a second interposer 314b which is positioned between the second board 312 and the third board 313 and connects the second board 312 and the third board 313. The interposers 314a and 314b may be referred to as an interposer via.

According to an embodiment, the circuit board 310 may accommodate components 315a and 315b. For example, the circuit board 310 may include a first component 315a positioned between the first board 311 and the second board 312 and a second component 315b positioned between the second board 312 and the third board 313. The components 315a and 315b may be electronic components for an operation of the electronic device 101 and/or be a heat dissipation component for dissipating heat generated in the electronic components. The heat dissipation component may be made of a thermal interface material and/or a heat conduction material.

According to an embodiment, in order to allow the electronic device 101 to slide, the frame 213 and the second cover member 221 may be spaced apart from each other. For example, a gap g may be formed between an upper surface 213c of the frame 213 and a lower surface 221d of the second cover member 221 to allow the electronic device 101 to slide. The heat transfer efficiency between the frame 213 and the second cover member 221 may be reduced due to an empty space (e.g., the gap g) between the frame 213 and the second cover member 221. For example, since the frame 213 and the second cover member 221 are spaced apart from each other, heat conduction between the upper surface 213c of the frame 213 and the lower surface 221d of the second cover member 221 may not be performed.

According to an embodiment, the heat dissipation member 320 may transfer at least a portion of the heat of a second housing (e.g., the second housing 202 in FIG. 4) to the frame 213 of a first housing (e.g., the first housing 201 in FIG. 4). For example, at least a portion of the heat generated in the processor 120 may be transferred to the frame 213 via the heat dissipation member 320. According to an embodiment, in a slide-in state (e.g., FIG. 2) of the electronic device 101, the heat dissipation member 320 may be in contact with the circuit board 310 and the frame 213. In a slide-in state of the electronic device 101, as the heat dissipation member 320 is in contact with the circuit board 310 and the frame 213, at least a portion of the heat (e.g., the heat generated in the processor 120) of the circuit board 310 may be transferred through heat conduction so that the heat conduction efficiency is improved. In a slide-in state of the electronic device 101, the circuit board 310 and the frame 213 are thermally coupled via the heat dissipation member 320. In a slide-out state of the electronic device 101, the heat dissipation member 320 is thermally decoupled to the circuit board 310 or the frame 213.

According to an embodiment (e.g., FIG. 9), the heat dissipation member 320 may be positioned between the circuit board 310 and the frame 213. In an embodiment, the heat dissipation member 320 may be attached to the circuit board 310. For example, the circuit board 310 may include a side surface portion 310a facing the frame 213, and the heat dissipation member 320 may be disposed on the side surface portion 310a. The side surface portion 310a may be an outer surface of the circuit board 310, which is oriented in the sliding direction (e.g., the Y-axis direction) of the electronic device 101. In an embodiment, the heat dissipation member 320 may be attached to the frame 213. For example, the frame 213 may include an outer surface 213b facing the circuit board 310. The heat dissipation member 320 may be disposed on the outer surface 213b of the frame 213.

According to an embodiment (e.g., FIG. 10), the second cover member 221 may include a side wall 222. For example, the circuit board 310 may be accommodated in the second cover member 221. The side wall 222 may protect at least a portion of the circuit board 310. For example, the side wall 222 may include a first side surface 222a facing the side surface portion 310a of the circuit board 310, and a second side surface 222b which is opposite to the first side surface 222a and faces the frame 213. According to an embodiment, the heat dissipation member 320 may be positioned between the second cover member 221 and the frame 213. For example, in an embodiment, the heat dissipation member 320 may be attached on the second side surface 222b of the side wall 222. In an embodiment, the heat dissipation member 320 may be attached on the outer surface 213b of the frame 213.

According to an embodiment, the heat dissipation member 320 may be a thermal interface material (TIM). For example, the heat dissipation member 320 may be a heat conductive material (e.g., thermal paste, thermal gap filler, thermal adhesive, or a thermal tape) having an adhesive property.

According to an embodiment, the heat dissipation member 320 may be compressible. In a slide-in state of the electronic device 101, the heat dissipation member 320 may be compressed so that the heat dissipation performance of the electronic device 101 is improved. For example, the distance between the processor 120 and the frame 213 may be reduced as the heat dissipation member 320 is compressed. As the heat dissipation member 320 is compressed, the density of the heat dissipation member 320 may be increased so that the heat conduction efficiency of the heat dissipation member 320 is improved.

According to an embodiment (e.g., FIG. 10), the electronic device 101 may include a heat conduction gel 340 (a thermal gel). According to an embodiment, the heat conduction gel 340 may be disposed on the second cover member 221. The heat conduction gel 340 may increase the amount of heat which is generated in the processor 120 and then transferred to the heat dissipation member 320 and/or the frame 213. For example, the heat conduction gel 340 may be in contact with the circuit board 310 and the side wall 222 of the second cover member 221. At least a portion of the heat generated in the processor 120 may be transferred to the frame 213 via the heat conduction gel 340, the side wall 222, and/or the heat dissipation member 320. The heat conduction gel 340 may be referred to as thermal grease and/or thermal paste.

According to an embodiment, the frame 213 may include an accommodation space 213d configured to accommodate a component of the electronic device 101. For example, a part (e.g., a motor 241) of the drive structure 240 may be positioned in the accommodation space 213d. At least a portion of the heat generated in the processor 120 may be transferred to a component positioned in the accommodation space 213d.

According to an embodiment, the electronic device 101 may include an auxiliary heat dissipation member 329 positioned in the accommodation space 213d. The auxiliary heat dissipation member 329 may be attached to the frame 213. The thermal capacity of the first housing (e.g., the first housing 201 in FIG. 8) may be increased by the auxiliary heat dissipation member 329.

The auxiliary heat dissipation member 329 may be a passage for allowing heat generated in the processor 120 positioned on the circuit board 310 to be transferred to the battery 289. For example, at least a portion of the heat generated in the processor 120 may be transferred to the battery 289 via the heat conduction gel 340, the side wall 222, the heat dissipation member 320, the auxiliary heat dissipation member 329, and/or the frame 213. Therefore, as the heat is dissipated, a maximum temperature of the processor 120 may be reduced.

The material of the auxiliary heat dissipation member 329 may be substantially the same as the material of the heat dissipation member 320. The auxiliary heat dissipation member 329 may be a thermal interface material (TIM). For example, the auxiliary heat dissipation member 329 may be a heat conductive material (e.g., thermal paste, a thermal gap filler, thermal adhesive, or a thermal tape) having an adhesive property.

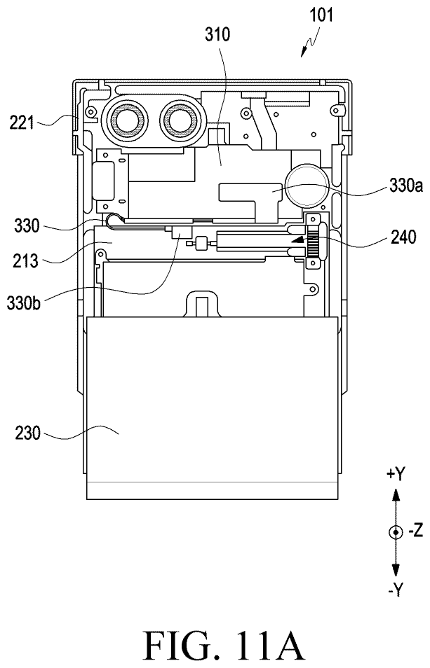

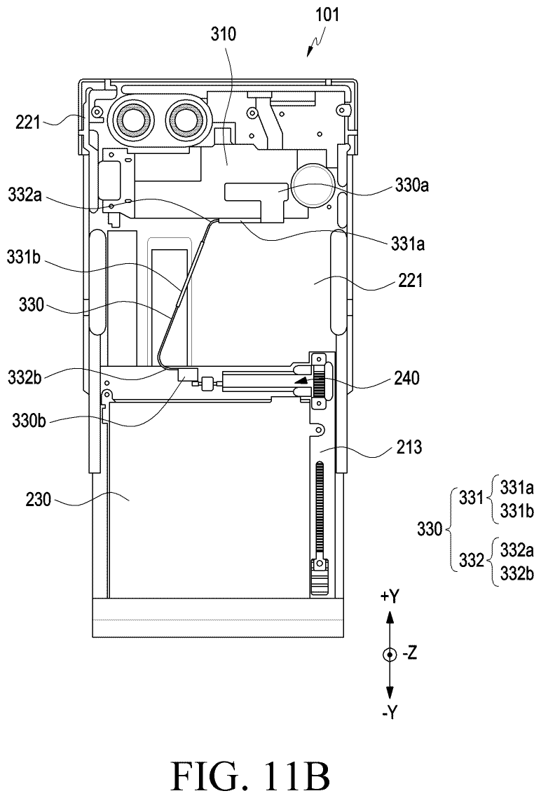

FIG. 11A is a rear view in a slide-in state of an electronic device including a connection member according to an embodiment of the disclosure.

FIG. 11B is a rear view in a slide-out state of an electronic device including a connection member according to an embodiment of the disclosure.

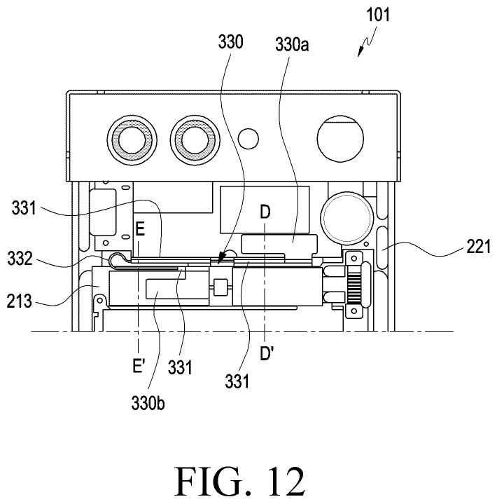

FIG. 12 is a rear view of an electronic device including a heat dissipation member and a connection member according to an embodiment of the disclosure.

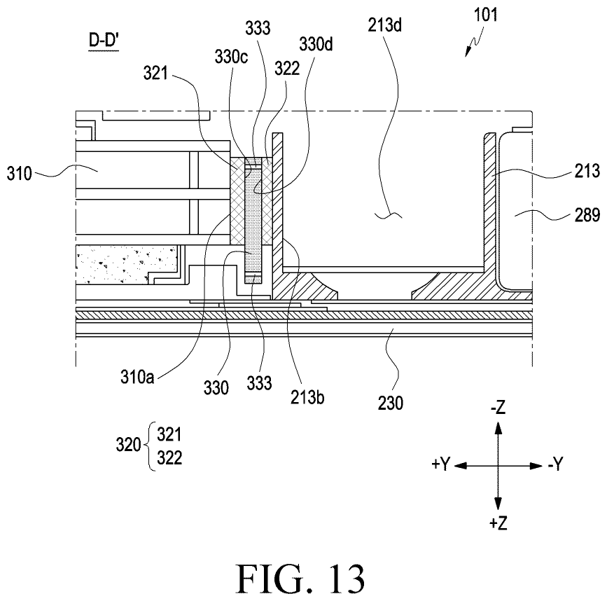

FIG. 13 is a cross-sectional view taken along line D-D′ in FIG. 12 according to an embodiment of the disclosure.

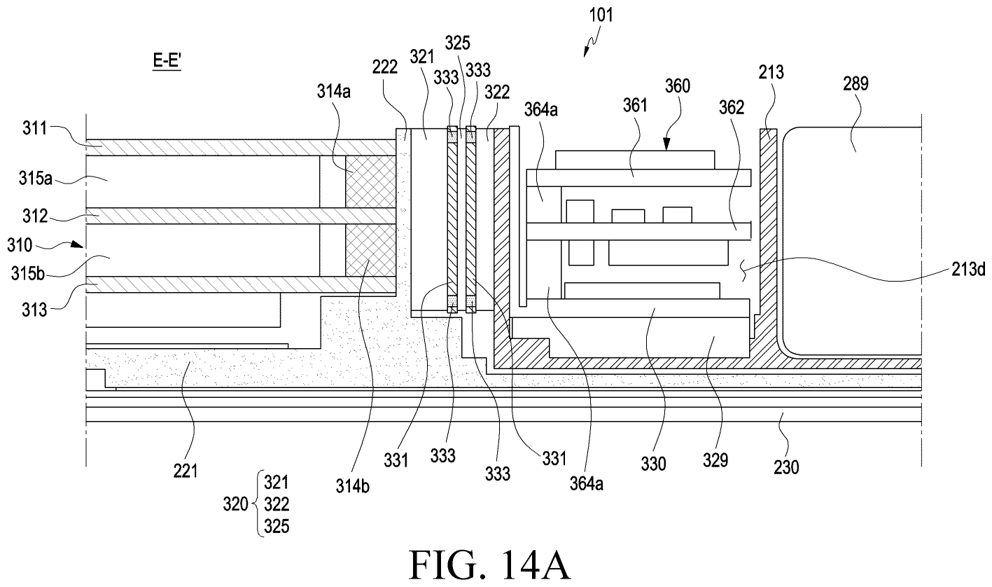

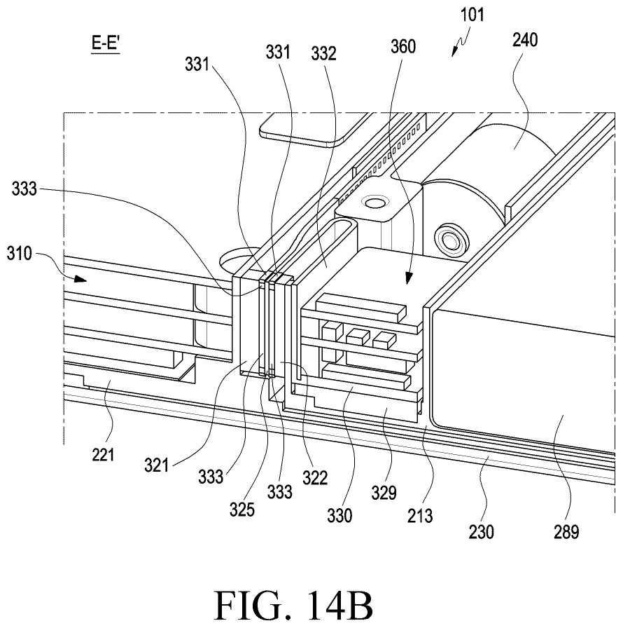

FIG. 14A is a cross-sectional view taken along line E-E′ in FIG. 12 according to an embodiment of the disclosure.

FIG. 14B is a cross-sectional perspective view taken along line E-E′ in FIG. 12 according to an embodiment of the disclosure.

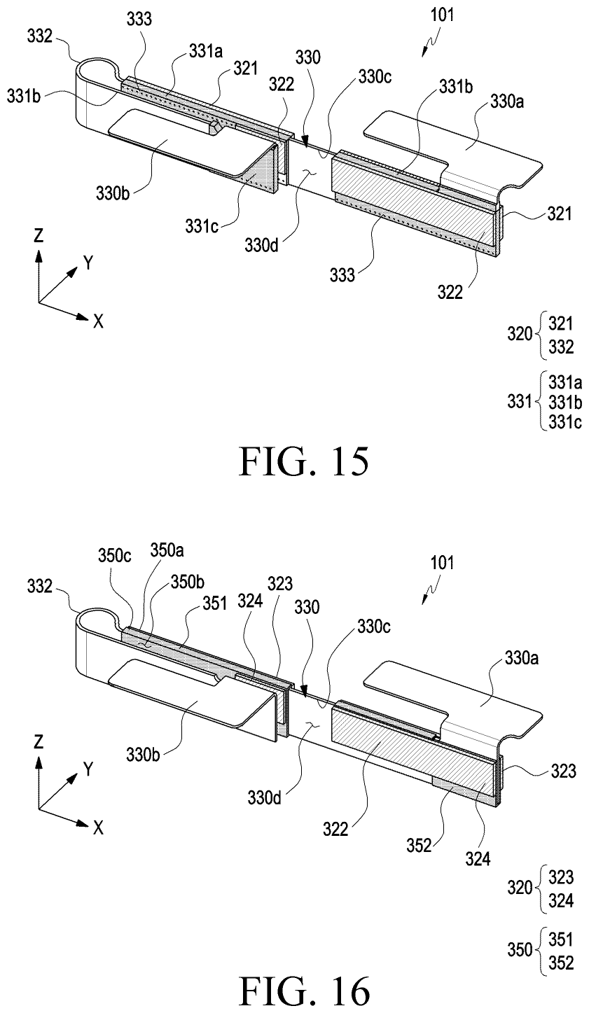

FIG. 15 is a perspective view of a heat dissipation member and a connection member according to an embodiment of the disclosure.

Referring to FIGS. 11A, 11B, 12, 13, 14A, 14B, and/or 15, an electronic device 101 may include a first housing 201 (e.g., the frame 213), a second housing (e.g., the second cover member 221), a display assembly 230, a battery 289, a drive structure 240, a circuit board 310, a heat dissipation member 320, an auxiliary heat dissipation member 329, and/or a connection member 330.

The configuration of the electronic device 101 in FIGS. 11A, 11B, 12, 13, 14A, 14B, and/or 15 may be entirely or partially the same as the configuration of the electronic device 101 in FIGS. 8 to 10. For example, the configuration of the first housing 201 (e.g., the frame 213), the second housing (e.g., the second cover member 221), the display assembly 230, the battery 289, the drive structure 240, the circuit board 310, the auxiliary heat dissipation member 329, and the heat dissipation member 320 in FIGS. 11A, 11B, 12, 13, 14A, 14B and/or 15 may be entirely or partially the same as the configuration of the first housing 201 (e.g., the frame 213), the second housing (e.g., the second cover member 221), the display assembly 230, the battery 289, the drive structure 240, the circuit board 310, the auxiliary heat dissipation member 329, and the heat dissipation member 320 in FIGS. 8, 9, and/or 10. For example, the circuit board 310 in FIG. 14A may include a first board 311, a second board 312, a third board 313, interposers 314a and 314b, and components 315a and 315b. The contents described in FIGS. 9 and 10 may be applied to the first board 311, the second board 312, the third board 313, the interposers 314a and 314b, and the components 315a and 315b in FIG. 14A.

According to an embodiment, the connection member 330 may electrically connect a component positioned in the first housing 201 and a component positioned in the second housing 202. For example, the connection member 330 may include a first end 330a connected to the circuit board 310 positioned in first housing 201, and a second end 330b which is opposite to first end 330a and is connected to a third circuit board 360 and/or a component (e.g., the drive structure 240) positioned in the second housing 202.

According to an embodiment, the connection member 330 may be bent or deformed based on the sliding movement of the electronic device 101. For example, the connection member 330 may include at least one second area 332. According to an embodiment, the second area 332 may include a (2-1) area 332a adjacent to the first end 330a and a (2-2)th area 332b which is spaced apart from the first area 332a and spaced apart from the second area 332b. According to an embodiment, the second area 332 may be referred to as a flexible area of the connection member 330. The (2-1)th area 332a may be referred to as a first flexible area, and the (2-2)th area 332b may be referred to as a second flexible area.

According to an embodiment, the connection member 330 may include at least one first area 331. For example, the first area 331 may include multiple first areas (e.g., the (1-1)th area 331a, the (1-2)th area 331b, and/or the (1-3)th area 331c) spaced apart from each other.

According to an embodiment, the first area 331 may be referred to as a rigid area of the connection member 330. The (1-1)th area 331a may be referred to as a first rigid area, the (1-2)th area 331b may be referred to as a second rigid area, and the (1-3)th area 331c may be referred to as a third rigid area. According to an embodiment, the first area 331 may have strength higher than the strength of the second area 332. For example, the first area 331 may be referred to as a part of a connection member 330 having flexibility higher than the second area 332.

According to an embodiment, the connection member 330 may be referred to as a rigid flexible printed circuit board (RFPCB).

According to an embodiment, in a slide-in state (e.g., FIG. 11A) of the electronic device 101, the connection member 330 may be positioned between the circuit board 310 and the frame 213. For example, the connection member 330 may include a first surface 330c and a second surface 330d opposite to the first surface 330c. In a slide-in state of the electronic device 101, the connection member 330 may be folded, the first surface 330c of the connection member 330 may face the circuit board 310 and the frame 213, and at least a portion of the second surface 330d thereof may be surrounded by the first surface 330c. A part of the first surface 330c of the connection member 330 may be in contact with the circuit board 310, and another part thereof may be in contact with a part (e.g., the outer surface 213b) of the frame 213.

According to an embodiment, the connection member 330 may include at least one via 333 for increasing heat conductivity. For example, the via 333 may include a material (e.g., metal) having heat conductivity higher than the connection member 330. According to an embodiment, the via 333 may be positioned in the first area 331 of the connection member 330. For example, the via 333 may be formed to penetrate the first surface 330c and the second surface 330d of connection member 330. According to an embodiment, the via 333 may be referred to as a thermal via or a heat dissipation via.

According to an embodiment, the connection member 330 may be electrically connected to the third circuit board 360 (e.g., the third circuit board 360 in FIG. 7).

The third circuit board 360 may be a multi-layer board including multiple boards. For example, the third circuit board 360 may include a fourth board 361 and a fifth board 362 which are stacked on each other. The fourth board 361 may be referred to as a primary board. The fifth board 362 may be referred to as a secondary board.

According to an embodiment, the third circuit board 360 may be an interposer substrate. For example, the third circuit board 360 may include interposers 364a and 364b. According to an embodiment, the interposer 364a may be a third interposer 364a which is positioned between the fourth board 361 and the fifth board 362 and connects the fourth board 361 and the fifth board 362.

According to an embodiment, the third circuit board 360 may be electrically connected to the connection member 330. For example, the third circuit board 360 may include a fourth interposer 364b which is positioned between the fifth board 362 and the connection member 330 and connects the fifth board 362 and the connection member 330. The interposers 364a and 364b may be referred to as an interposer via.

According to an embodiment, a third circuit board 360 may be positioned in an accommodation space 213d of a frame 213. The third circuit board 360 may be connected to the connection member 330.

According to an embodiment, the heat dissipation member 320 may be disposed on the connection member 330. For example, the heat dissipation member 320 may be disposed on the first area 331 of the connection member 330. According to an embodiment, the heat dissipation member 320 may cover the via 333.

According to an embodiment, the heat dissipation member 320 may be disposed on the first surface 330c and the second surface 330d of the connection member 330.

According to an embodiment, the heat dissipation member 320 may include multiple heat dissipation members 321 and 322 spaced apart from each other. For example, the heat dissipation member 320 may include a first heat dissipation member 321 disposed on the first surface 330c of the connection member 330, and a second heat dissipation member 322 disposed on the second surface 330d of the connection member 330. According to an embodiment, the via 333 may be positioned between the heat dissipation members 320. For example, the via 333 may be covered by the first heat dissipation member 321 and the second heat dissipation member 322.

According to an embodiment, the heat dissipation member 320 may be disposed on the first area 331 of the connection member 330. For example, the heat dissipation member 320 may include the first heat dissipation member 321 positioned between the second cover member 221 and the connection member 330, and the second heat dissipation member 322 positioned between the frame 213 and the connection member 330. According to an embodiment, the heat dissipation member 320 may include an intermediate heat dissipation member 325 positioned between the first areas 331 of the connection member 330.

According to an embodiment, at least a portion of the heat generated in a processor (e.g., the processor 120 in FIG. 8) may be transferred to the frame 213 and/or battery 289 via the circuit board 310, the via 333 positioned in the connection member 330, and the heat dissipation member 320 (e.g., the first heat dissipation member 321, the intermediate heat dissipation member 325, and the second heat dissipation member 322).

According to an embodiment, the auxiliary heat dissipation member 329 may be positioned between the frame 213 and the connection member 330. At least a portion of the heat generated in components mounted to the third circuit board 360 and/or the connection member 330 may be transferred to the frame 213 and/or the battery 289 through the auxiliary heat dissipation member 329.

FIG. 16 is a perspective view of a connection member to which a graphite sheet and a heat dissipation member are arranged according to an embodiment of the disclosure.

Referring to FIG. 16, an electronic device 101 may include a heat dissipation member 320, a connection member 330, and a heat dissipation sheet 350. The configuration of the heat dissipation member 320 and the connection member 330 in FIG. 16 may be entirely or partially the same as the configuration of the heat dissipation member 320 and the connection member 330 in FIG. 15.

According to an embodiment, at least a portion of the connection member 330 may be bent. For example, the connection member 330 may be a flexible printed circuit board (FPCB).

According to an embodiment, the heat dissipation sheet 350 may be bent based on deformation of the connection member 330. The heat dissipation sheet 350 may include graphite. The heat dissipation sheet 350 may be referred to as a graphite sheet.

According to an embodiment, the heat dissipation sheet 350 may surround at least a portion of the connection member 330. For example, the heat dissipation sheet 350 may include a first graphite area 350a disposed on the first surface 330c of the connection member 330, and a second graphite area 350b disposed on the second surface 330d of the connection member 330. According to an embodiment, the heat dissipation sheet 350 may include a third graphite area 350c configured to connect the first graphite area 350a and the second graphite area 350b. According to an embodiment, the first graphite area 350a may face a third heat dissipation member 323, and the second graphite area 350b may face a fourth heat dissipation member 324. For example, the first graphite area 350a may be positioned between the third heat dissipation member 323 and the connection member 330, and the second graphite area 350b may be positioned between the fourth heat dissipation member 324 and the connection member 330. The third graphite area 350c may thermally connect the first graphite area 350a and the second graphite area 350b. For example, at least a portion of the heat of the first graphite area 350a may be transferred to the second graphite area 350b through the third graphite area 350c.

According to an embodiment, the heat dissipation sheet 350 may include multiple heat dissipation sheets 351 and 352 spaced apart from each other. For example, the heat dissipation sheet 350 may include a first heat dissipation sheet 351 and a second heat dissipation sheet 352 spaced apart from the first heat dissipation sheet 351.

According to an embodiment, the heat dissipation member 320 may be disposed on the heat dissipation sheet 350. According to an embodiment, the heat dissipation member 320 may include multiple heat dissipation members 323 and 324 spaced apart from each other. For example, the heat dissipation member 320 may include a third heat dissipation member 323 disposed on the first graphite area 350a of the heat dissipation sheet 350, and a fourth heat dissipation member 324 disposed on the second graphite area 350b of the heat dissipation sheet 350.

According to an embodiment, the shape of the heat dissipation sheet 350 may be optional. For example, in an embodiment, the heat dissipation sheet 350 may include two third graphite areas 350c. The heat dissipation sheet 350 may have the shape of the Korean letter “ [symbol] ”. In an embodiment, the heat dissipation sheet 350 may include one third graphite area 350c. The heat dissipation sheet 350 may have the shape of the Korean letter “ [symbol] ”.

According to an embodiment, at least a portion of the heat generated in a processor (e.g., the processor 120 in FIG. 8) may be transferred to a frame (e.g., the frame 213 in FIG. 7) through the heat dissipation sheet 350 and the heat dissipation member 320. For example, at least a portion of the heat generated in the processor 120 may be transferred to the frame 213 through the third heat dissipation member 323, the first graphite area 350a, the third graphite area 350c, the second graphite area 350b, and the fourth heat dissipation member 324.

An electronic device (for example, a mobile terminal) may include a display, the shape of which has a flat surface or a flat surface and a curved surface. An electronic device including a display may have a limitation in implementing a screen which is larger than the size of the electronic device itself due to a fixed display structure. Accordingly, an electronic device including a rollable display are being researched.

Electronic devices are becoming miniaturization and lightweight in order to maximize portability and convenience for users, and integrated components are being mounted in smaller spaces in order to achieve high performance. Accordingly, components used in an electronic device may have higher temperature due to high performance, and the heat generated in the components of the electronic device may affect components adjacent thereto so that the whole performance of the electronic device is degraded.

In implementing a rollable electronic device, it may be difficult to secure a heat dissipation structure while allowing structures of the electronic device to relatively move (e.g., slide) with respect to each other. For example, in a rollable electronic device, an empty space between structures may be required for sliding movement of a display. Heat dissipation performance of an electronic device may be degraded due to the empty space between the structures.

According to an embodiment of the disclosure, in a slide-in state of an electronic device, the electronic device including a heat dissipation member capable of transferring heat generated in a processor disposed at one structure (e.g., a second housing) to another structure (e.g., a first housing) can be provided.

The problem to solve in the disclosure is not limited to the mentioned problem, and may be variously expanded within a scope not departing from the idea and the range of the disclosure.

According to an embodiment of the disclosure, an electronic device can dissipate heat generated in a processor by using a heat dissipation member.

In addition, various effects directly or indirectly identified through the document may be provided.

According to an embodiment of the disclosure, an electronic device (e.g., the electronic device 101 in FIG. 2) may include a first housing (e.g., the first housing 201 in FIG. 7) including a first cover member (e.g., the first cover member 211 in FIG. 7) and a frame (e.g., the frame 213 in FIG. 7) positioned in the first cover member, a second housing (e.g., the second housing 202 in FIG. 7) which includes a second cover member (e.g., the second housing 202 in FIG. 7) having at least a portion accommodated in the first cover member and is configured to slide relative to the first housing, a display (e.g., the display 203 in FIG. 2) configured to be unfolded based on the sliding movement of the second housing, a circuit board (e.g., the circuit board 248 in FIG. 7 or the circuit board 310 in FIG. 8) disposed on the second cover member and configured to accommodate a processor (e.g., the processor 120 in FIG. 8), and a heat dissipation member (e.g., the heat dissipation member 320 in FIG. 8) positioned between the circuit board and the frame.

The heat dissipation member may be positioned between the circuit board and the frame, and thus the heat dissipation member may transfer at least a portion of the heat generated in the processor to the frame. The heat of the processor positioned in the second housing may be dissipated to the first housing so as to reduce a temperature of the processor.

According to an embodiment, the circuit board may include a side surface portion (e.g., the side surface portion 310a in FIG. 8) facing the frame. The frame may include an outer surface (e.g., the outer surface 213b in FIG. 8) facing the side surface portion, and an upper surface (e.g., the upper surface 213c in FIG. 9) facing the second cover member. The heat dissipation member may be positioned between the side surface portion and the outer surface.

According to an embodiment, the second cover member may include a side wall (e.g., the side wall 222 in FIG. 10) surrounding at least a portion of the circuit board, and the heat dissipation member may be positioned between the side wall and the frame.

According to an embodiment, the electronic device may further include a connection member (e.g., the connection member 330 in FIG. 11B) including a first end (e.g., the first end 330a in FIG. 11B) positioned in the first housing, and a second end (e.g., the second end 330b in FIG. 111B) positioned in the second housing. The heat dissipation member may be disposed on the connection member.

The heat dissipation member may be disposed on the connection member, so that the area of components, which is in contact with the heat dissipation member, is increased, and the degree, in which the heat generated in the processor positioned in the second housing is transferred to the first housing, is be increased.

According to an embodiment, the connection member may include at least one first area (e.g., the first area 331 in FIG. 15), at least one second area (e.g., the second area 332 in FIG. 15), and multiple vias (e.g., the vias 333 in FIG. 15) positioned in the first area.

According to an embodiment, the connection member may include a first surface (e.g., the first surface 330c in FIG. 15) and a second surface (e.g., the second surface 330d in FIG. 15) opposite to the first surface. The heat dissipation member may include a first heat dissipation member (e.g., the first heat dissipation member 321 in FIG. 15) disposed on the first surface of the connection member, and a second heat dissipation member (e.g., the second heat dissipation member 322 in FIG. 15) disposed on the second surface of the connection member. The multiple vias may be positioned between the first heat dissipation member and the second heat dissipation member. The vias may have heat conductivity higher than the heat conductivity of the connection member. By the vias, the heat transfer between the first heat dissipation member and the second heat dissipation member may be improved.

According to an embodiment, the electronic device may further include a heat dissipation sheet (e.g., the heat dissipation sheet 350 in FIG. 16) which surrounds at least a portion of the connection member and includes graphite.

According to an embodiment, the heat dissipation sheet may include a first graphite area (e.g., the first graphite area 350a in FIG. 16) facing the circuit board, a second graphite area (e.g., the second graphite area 350b in FIG. 16) facing the frame, and at least one third graphite area (e.g., the third graphite area 350c in FIG. 16) configured to connect the first graphite area and the second graphite area. The heat dissipation member may include a third heat dissipation member (e.g., the third heat dissipation member 323 in FIG. 16) disposed on the first graphite area, and a fourth heat dissipation member (e.g., the fourth heat dissipation member 324 in FIG. 16) disposed on the second graphite area.

According to an embodiment, the heat dissipation member may be configured to be compressed based on the sliding movement of the second housing. The heat dissipation member may be compressed to improve the heat conduction efficiency thereof in a slide-in state of the electronic device.

According to an embodiment, the electronic device may be configured such that at least a portion of the heat generated in the processor is transferred to the frame through the heat dissipation member. The heat generated in the processor may be transferred to the frame so as to reduce a temperature (the internal temperature or the external temperature) of the processor.

According to an embodiment, the heat dissipation member may be made of a thermal interface material (TIM).

According to an embodiment, an upper surface (e.g., the upper surface 213c in FIG. 9) of the frame may be spaced apart from a lower surface (e.g., the lower surface 221d in FIG. 9) of the second cover member in a slide-in state of the electronic device.

According to an embodiment, the electronic device may include a drive structure (e.g., the drive structure 240 in FIG. 4) configured to slide the second housing relative to the first housing. The drive structure may include a motor (e.g., the motor 241 in FIG. 6) configured to generate a drive force for moving the second housing relative to the first housing and disposed in the frame, a gear (e.g., the gear 244 in FIG. 6) connected to the motor, and a rack (e.g., the rack 242 in FIG. 6) connected to the second housing and configured to mesh with the gear.

According to an embodiment, the electronic device may include a multi-bar structure (e.g., the multi-bar structure 232 in FIG. 4) configured to support at least a portion of the display, and a guide rail (e.g., the guide rail 250 in FIG. 4) which includes a slit (e.g., the slit 251 in FIG. 4) configured to guide a movement of the multi-bar structure and is connected to the frame.

According to an embodiment, the display may include a first display area (e.g., the first display area A1 in FIG. 3) connected to the second housing, and a second display area (e.g., the second display area A2 in FIG. 3) which extends from the first display area and is configured to be rolled or unfold based on the sliding movement of the second housing.

According to an embodiment of the disclosure, an electronic device (e.g., the electronic device 101 in FIG. 2) may include a first housing (e.g., the first housing 201 in FIG. 3), a second housing (e.g., the second housing 202 in FIG. 3) configured to slide relative to the first housing, a display (e.g., the display 203 in FIG. 3) configured to be unfolded based on the sliding movement of the second housing, a circuit board (e.g., the circuit board 310 in FIG. 8) disposed in the second housing and configured to accommodate a processor (e.g., the processor 120 in FIG. 8), a connection member (e.g., the connection member 330 in FIG. 11B) including a first end (e.g., the first end 330a in FIG. 11B) disposed in the first housing and a second end (e.g., the second end 330b in FIG. 11B) disposed in the second housing, and a heat dissipation member (e.g., the heat dissipation member 320 in FIG. 15) disposed on the connection member, the heat dissipation member being configured to be in contact with the circuit board and the first housing in a slide-in state of the electronic device.

According to an embodiment, the connection member may include at least one first area (e.g., the first area 331 in FIG. 15), at least one second area (e.g., the second area 332 in FIG. 15), and multiple vias (e.g., the vias 333 in FIG. 15) configured to penetrate a first surface (e.g., the first surface 330c in FIG. 15) and the second surface (e.g., the second surface 330d in FIG. 15) of the first area, the second surface being opposite the first surface.

According to an embodiment, the heat dissipation member may include a first heat dissipation member (e.g., the first heat dissipation member 321 in FIG. 15) disposed on the first surface of the connection member, and a second heat dissipation member (e.g., the second heat dissipation member 322 in FIG. 15) disposed on the second surface of the connection member.

According to an embodiment, the electronic device may further include a heat dissipation sheet (e.g., the heat dissipation sheet 350 in FIG. 16) surrounding at least a portion of the connection member and including graphite.

According to an embodiment, the heat dissipation sheet may include a first graphite area (e.g., the first graphite area 350a in FIG. 16) facing the circuit board, a second graphite area (e.g., the second graphite area 350b in FIG. 16) facing the first housing, and at least one third graphite area (e.g., the third graphite area 350c in FIG. 16) configured to connect the first graphite area and the second graphite area. The heat dissipation member may include a third heat dissipation member (e.g., the third heat dissipation member 323 in FIG. 16) disposed on the first graphite area, and a fourth heat dissipation member (e.g., the fourth heat dissipation member 324 in FIG. 16) disposed on the second graphite area.

The electronic device including a heat dissipation member of the disclosure described above is not limited by the above-described embodiments and drawings, and it will be obvious to a person skilled in the technical field, to which the disclosure belongs, that various substitutions, modifications, and changes are possible within the technical scope of the disclosure.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device comprising:
a first housing having a first cover member, and a frame disposed within the first cover member, the frame including an outer surface;
a second housing having a second cover member, at least a portion of which is accommodated within the first cover member, wherein the second housing is configured to slide relative to the first housing between a slide-in state and a slide-out state;
a display configured to be unfolded based on a sliding movement of the second housing;
a circuit board disposed on the second cover member and accommodating an application processor; and
a heat dissipation member disposed between the circuit board and the frame, wherein the circuit board and the frame are thermally coupled via the heat dissipation member in the slide-in state and the heat dissipation member is thermally decoupled to the circuit board or the frame in the slide-out state.

2. The electronic device of claim 1,
wherein the circuit board comprises a side surface portion facing the frame,
wherein the outer surface faces the side surface portion, and
wherein the heat dissipation member is disposed between the side surface portion and the outer surface.

3. The electronic device of claim 1,
wherein the second cover member comprises a side wall surrounding at least a portion of the circuit board, and
wherein the heat dissipation member is disposed between the side wall and the frame.

4. The electronic device of claim 1, further comprising:
a connection member comprising a first end positioned in the first housing and a second end positioned in the second housing,
wherein the heat dissipation member is disposed on the connection member.

5. The electronic device of claim 4, wherein the connection member comprises at least one first area, at least one second area, and a plurality of vias positioned in the first area.

6. The electronic device of claim 5,
wherein the connection member comprises a first surface and a second surface opposite to the first surface,
wherein the heat dissipation member comprises a first heat dissipation member disposed on the first surface of the connection member and a second heat dissipation member disposed on the second surface of the connection member, and
wherein the plurality of vias are disposed between the first heat dissipation member and the second heat dissipation member.

7. The electronic device of claim 6, further comprising:
a heat dissipation sheet surrounding at least a portion of the connection member and comprising graphite.

8. The electronic device of claim 7,
wherein the heat dissipation sheet comprises a first graphite area facing the circuit board, a second graphite area facing the frame, and at least one third graphite area connecting the first graphite area and the second graphite area, and
wherein the heat dissipation member comprises a third heat dissipation member disposed on the first graphite area and a fourth heat dissipation member disposed on the second graphite area.

9. The electronic device of claim 1, wherein the heat dissipation member is configured to be compressed based on the sliding movement of the second housing.

10. The electronic device of claim 1, wherein at least a portion of heat generated by the application processor is transferred to the frame through the heat dissipation member.

11. The electronic device of claim 1, wherein the heat dissipation member is a thermal interface material (TIM).

12. The electronic device of claim 1, wherein the frame comprises an upper surface spaced apart from a lower surface of the second cover member in the slide-in state of the electronic device.

13. The electronic device of claim 1, further comprising:
a drive structure for sliding the second housing relative to the first housing,
wherein the drive structure comprises:
a motor configured to generate a drive force for moving the second housing relative to the first housing and disposed in the frame,
a gear connected to the motor, and
a rack connected to the second housing and configured to mesh with the gear.

14. The electronic device of claim 1, further comprising:
a multi-bar structure supporting at least a portion of the display; and
a guide rail having a slit configured to guide a movement of the multi-bar structure, wherein the guide rail is connected to the frame.

15. The electronic device of claim 1, wherein the display comprises a first display area connected to the second housing and a second display area which extends from the first display area and is configured to be rolled or unrolled based on the sliding movement of the second housing.
